(19) United States
(12) Patent Application Publication
(10) Pub. No.: US 2007/0259507 A1
(43) Pub. Date: Nov. 8, 2007

(54) Manufacturing method of semiconductor device

(75) Inventor: Satoshi Matsuda, Oita-ken (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/725,561

(22) Filed: Mar. 20, 2007

(30) Foreign Application Priority Data
Mar. 20, 2006 (JP) JP2006-076289

(51) Int. Cl. H01L 21/76; H01L 21/00

(52) U.S. Cl. 438/424; 438/799; 257/E21.002

(57) ABSTRACT

In a manufacturing method of semiconductor device, initially, a trench pattern is laid out along a <100> direction of a (100) silicon substrate. Next, a trench is formed in the silicon substrate based on the laid-out trench pattern. Further, the silicon substrate with the trench formed therein is annealed in a low-pressure reducing atmosphere to cause silicon migration. This reduces the radius of curvature of a corner portion of the formed trench pattern. Consequently, changes of the contact area with an electrode and a contact can be suppressed in an active area isolated by the trench pattern, and characteristic deterioration caused by changes of the contact area can be suppressed.

### CROSS-REFERENCE TO RELATED APPLICATIONS

This application is based upon and claims the benefit of priority from the prior Japanese Patent Application No. 2005-263798 filed on Mar. 20, 2006, the entire contents of which are incorporated herein by reference.

### BACKGROUND OF THE INVENTION

1. Field of the Invention

The present invention relates to a manufacturing method of a semiconductor device using a silicon substrate.

2. Description of the Related Art

In processes for manufacturing a semiconductor device, a silicon substrate, and a polysilicon film and other insulating films deposited on the substrate are patterned. Used for patterning are lithography and etching; there exist optical limits in lithography, and controllability limits in etching. Therefore, a portion that is to be a corner of a pattern (hereinafter referred to as a “pattern corner portion”) cannot be formed to have a right angle but has roundness.

In patterns, there are variations in size and misalignment between patterns. With the variations and misalignment, the channel width defined by the width of an overlapping portion of an active area and a gate electrode changes, and as a result the drive current of a metal-oxide-semiconductor field-effect transistor (MOSFET) changes. Further, the overlapping area of the active area and a contact is reduced, increasing contact resistance. Thus, characteristics vary, adversely affecting operations of an integrated circuit. For this reason, the layout of patterns is normally provided with some degree of margin.

With reduction of the design rule, for example, an overlapping margin of an active area and a gate electrode needs to be less than or equal to approximately 0.1 μm in 90 nm and 65 nm generations.

However, since a roundness shape of a pattern corner portion formed by actual processing has the radius of curvature of approximately 0.1 μm, a substantial margin cannot be obtained. Therefore, it is difficult to suppress characteristic variations and deterioration.

On the other hand, T. Saito, et. al. “Trench Transformation Technology using Hydrogen Annealing for Realizing Highly Reliable Device Structure with Thin Dielectric Films”, 1998 VLSI Sympo. and S. Matsuda, et. al. “Novel Corner Rounding Process for Shallow Trench Isolation utilizing MSTS (Micro-Structure Transformation of Silicon)”, 1998 IEDM disclose that silicon migration is induced by annealing in a low-pressure reducing atmosphere. A method of deforming a processed shape by heat treatment using this phenomenon is disclosed in FIG. 8 of Japanese Patent Application Laid-Open No. 2000-357779 and other documents. However, the method has not achieved controlling a shape of a pattern corner portion.

### SUMMARY OF THE INVENTION

According to an embodiment of the invention, there is provided a manufacturing method of a semiconductor device in which, initially, a trench pattern is laid out along a <100> direction of a (100) silicon substrate; next, a trench is formed in the silicon substrate based on the laid-out trench pattern; and further, the silicon substrate with the trench formed therein is annealed in a low-pressure reducing atmosphere.

### BRIEF DESCRIPTION OF THE DRAWINGS

The accompanying drawing, which are incorporated in and constitute a part of the specification, illustrate embodiments of the invention, and together with the general description given above and the detailed description of the embodiments given below, serve to explain the principles of the invention.

FIGS. 1A, 1B, and 1C are conceptual views of a layout pattern, a processed shape, and a modification shape of a semiconductor device relating to an embodiment of the present invention, respectively;

FIG. 2 shows a flow of manufacturing processes of a semiconductor device relating to an embodiment of the present invention;

FIGS. 3A and 3B show a manufacturing process of semiconductor device relating to an embodiment of the present invention;

FIGS. 4A and 4B show a manufacturing process of semiconductor device relating to an embodiment of the present invention;

FIGS. 5A and 5B show a manufacturing process of semiconductor device relating to an embodiment of the present invention;

FIGS. 6A and 6B show a manufacturing process of semiconductor device relating to an embodiment of the present invention;

FIGS. 7A and 7B show a manufacturing process of semiconductor device relating to an embodiment of the present invention;

FIGS. 8A and 8B show a manufacturing process of semiconductor device relating to an embodiment of the present invention;

FIG. 9 shows a layout pattern of the semiconductor device relating to an embodiment of the present invention;

FIG. 10 shows a processed shape of the pattern relating to an embodiment of the present invention;

FIG. 11 shows a processed shape of the pattern relating to an embodiment of the present invention;

FIG. 12 shows a modification shape of the pattern relating to an embodiment of the present invention;

FIG. 13 shows the modification shape of the pattern relating to an embodiment of the present invention.

### DETAILED DESCRIPTION OF THE EMBODIMENT

An embodiment of the invention will be described below with reference to the accompanying drawings.

### First Embodiment

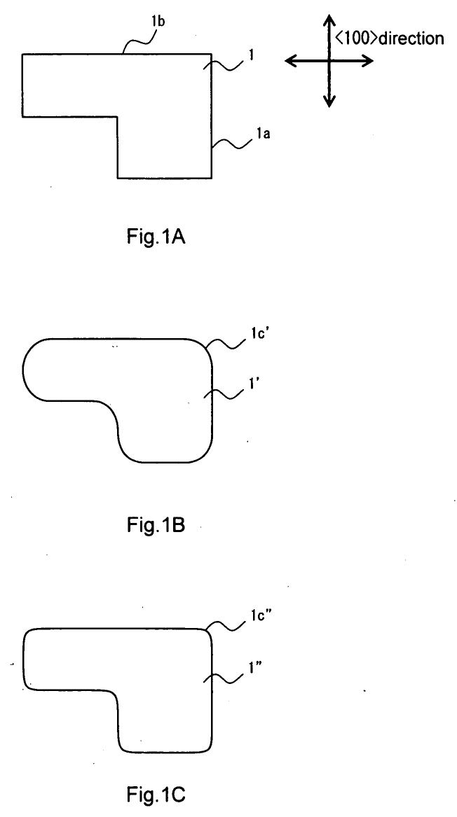

FIGS. 1A, 1B, and 1C are conceptual views of a layout pattern, a processed shape, and a modification shape of a semiconductor device formed by the present embodiment of the invention, respectively.

As shown in FIG. 1A, a pattern is laid out along a <100> direction. That is, the layout of the pattern is such that sides 1A and 1B of an active area 1 are arranged in the <100> direction.

According to the layout, as shown in FIG. 1B, a pattern of an active area 1′ having a pattern corner portion 1c′ that has roundness is formed on a (100) surface of a silicon substrate by conventional processes.

By annealing this pattern under predetermined conditions, as shown in FIG. 1C, the pattern is deformed in a direction of reducing the radius of curvature of the roundness of a pattern corner portion 1c″ (acute angle), forming an active area 1″.

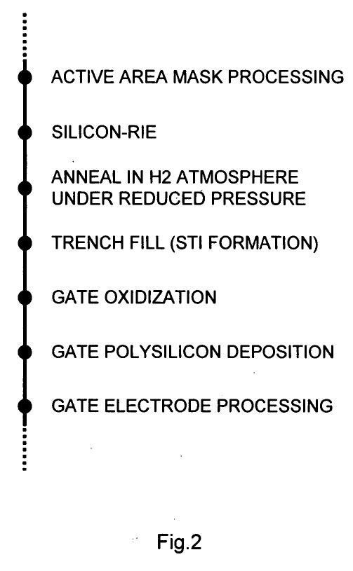

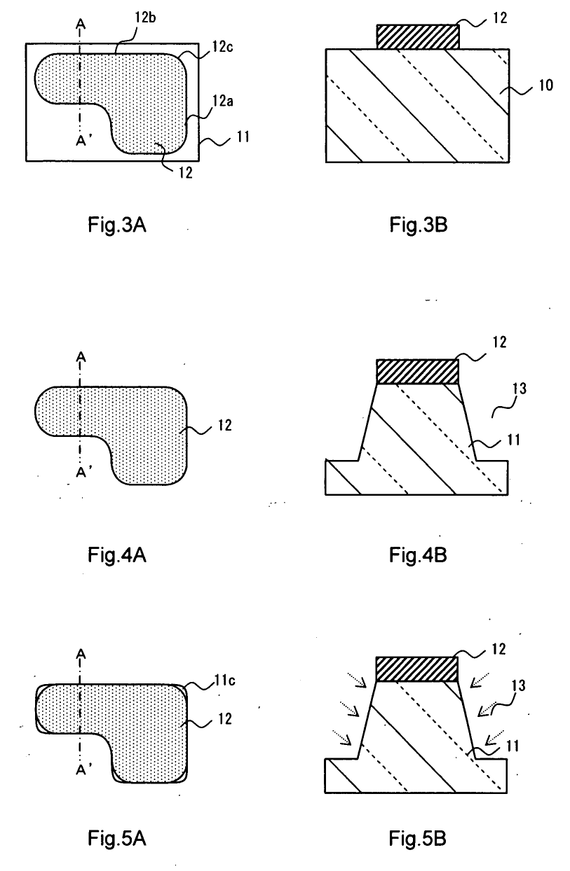

A method for forming a pattern of a semiconductor device will be specifically described below referring to FIGS. 3A to 8A, which are top views showing manufacturing processes of semiconductor device, and FIGS. 3B to 8B, which are cross sectional views taken along the line A-A′ of FIGS. 3A to 8A with processes for forming shallow trench isolation (STI) generally used for element isolation of a semiconductor device, the flow of which is shown in FIG. 2, taken as an example.

First, as shown in FIGS. 3A and 3B, a mask 12 of a pattern of an active area is formed on the (100) surface of a silicon substrate 10. The mask 12 is laid out laid out so that sides 12a and 12b, which are to be sides of an active area, are arranged along the crystal orientation of a silicon substrate 11, or along the <100> direction by adjusting (turning) a mask position in lithography.

An insulating film such as a SiN film or a chemical vapor deposition (CVD) oxide film, or a multilayered film of these films is formed and patterned by conventional lithography and conventional etching processing such as reactive ion etching (RIE), thereby forming the mask 12 for use in substrate processing.

A corner portion 12c of the formed mask 12 has a roundness shape defined by optical limits and limits of shaping processes. The roundness shape has, for example in the 90 nm and 65 nm generations, a radius of curvature of approximately 0.1 μm by lithography using an ArF excimer laser and conventional etching.

Next, as shown in FIGS. 4A and 4B, by using the formed mask 12, the silicon substrate 10 is etched by a predetermined amount, e.g., approximately 300 nm in the 90 nm and 65 nm generations by a conventional method such as RIE, thereby forming an active area 11 and a trench 13.

Next, as shown in FIGS. 5A and 5B, annealing is performed in a low-pressure reducing atmosphere, e.g., in an H₂ atmosphere under reduced pressure. The annealing conditions include the temperature: 950° C. and pressure: 380 Torr for 60 seconds. For example, the (100) surface that is to be a channel of a MOSFET is protected with a mask.

Annealing in a low-pressure reducing atmosphere induces silicon migration. Although the shape of the mask 12 made of an insulating film remains unchanged, a pattern corner portion 11c of the active area 11 is deformed to be acutely angled, that is, deformed in a direction of reducing the radius of curvature.

This deformation occurs because a silicon crystal surface flows due to silicon migration to increase the area of the surface where the surface energy is stabilized. In other words, the surface energy of the silicon crystal surface increases in the order of (111): 8.5 eV/nm²<(100): 9.0 eV/nm²<(110): 10.4 eV/nm². Therefore, after migration, the area of (100) surface where the surface energy is more stabilized than the area of the (110) surface increases. That is, in the case where the pattern is laid out in the <100> direction, by the silicon migration, the area of (100) surface shifts in a direction of increasing, changing the shape of the pattern corner portion to be acutely angled.

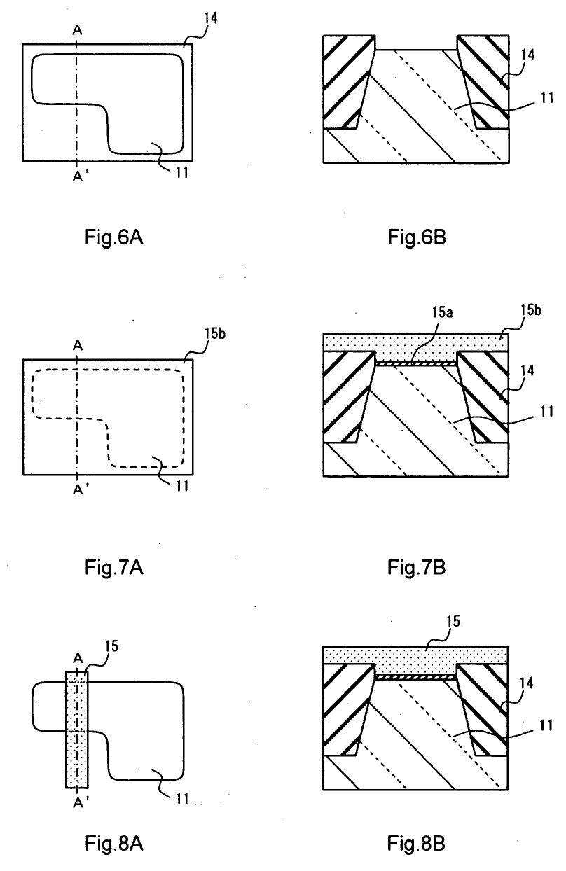

Next, like conventional device isolation processes, as shown in FIGS. 6A and 6B, after the inside of the trench 13 is oxidized and an insulating film 14 is deposited, an element isolation structure is formed through CMP and other processes.

Next, as shown in FIGS. 7A and 7B, a gate portion is oxidized to form a gate insulating film 15a, and a polysilicon film 15b for a gate electrode is deposited.

Then, as shown in FIGS. 8A and 8B, a gate electrode 15 is formed by conventional lithography. Further, like conventional processes of manufacturing a semiconductor device, an interlayer insulating film, a contact, upper layer wiring and so on are formed. A semiconductor device is thereby formed.

As described above, a trench pattern is formed on a silicon substrate and thereafter is annealed in a low-pressure reducing atmosphere, allowing the pattern corner portion to be deformed to an acute angle.

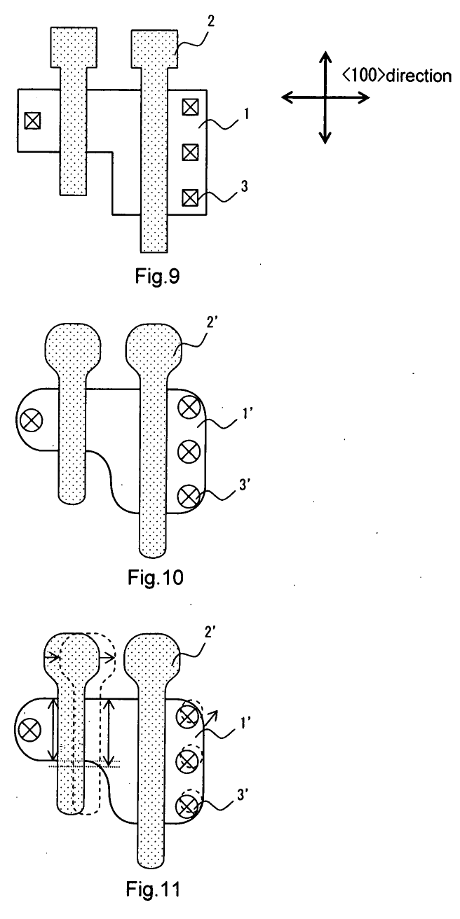

A gate electrode 2 and a contact 3 are laid out for the active area 1, for example, as shown in FIG. 9, and a gate electrode 2′ and a contact 3′ are formed on the active area 1′ with the pattern corner portion having roundness formed by conventional processes as shown in FIG. 10. With the margin based on the design rule, there is concern that if misalignment indicated by doted lines occurs as shown in FIG. 11, a channel under a gate or a contact will overlap with the roundness of the pattern corner portion. In this conventional case, the distance between the pattern corner portion and the gate or the contact needs to be larger.

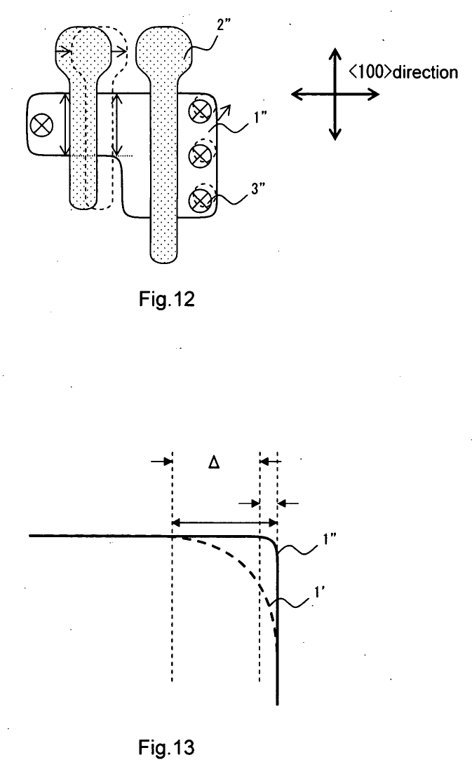

In contrast, in the embodiment, the pattern corner portion of the active area 1″ is deformed to an acute angle as shown in FIG. 12. Therefore, as in the enlarged view of the pattern corner portion shown in FIG. 13, the active area 1″ after deformation indicated by continuous lines permits the margin to be larger by Δ than that of the active area 1′ before deformation indicated by doted lines.

The increase of the margin can suppress changes of the contact area of the gate electrode 2″ and the contact 3″ with the channel width and the active area due to misalignment caused when the gate electrode 2″ and the contact 3″ are formed. Further, variations in characteristics and adverse effects on integrated circuit operations that result from changes of the contact area can be suppressed.

Thus, it is made possible to shrink the chip size due to reduction of the design rule and to improve yields of semiconductor devices.

In the embodiment, the conditions that the annealing atmosphere is an H₂ atmosphere under reduced pressure, the temperature: 950° C., and pressure: 380 Torr for 60 seconds have been mentioned. However, the conditions are not limited to the above conditions. Another conditions, such as a pressure of 10 Torr and temperatures in the range of 900 to 1100° C. or a temperature of 1000° C. and pressures less than or equal to 100 Torr, under which silicon migration occurs can be accepted.

In the embodiment, a pattern is laid out so as to be along the <100> direction on the (100) surface of the silicon substrate 10. Therefore, it is preferable to use a circular silicon substrate to which processing for crystal orientation identification called a notch or orientation flat is applied in the <100>direction of the silicon substrate with the (100) surface upward. With a silicon substrate having a notch or orientation flat formed in the <100> direction on the wafer, the layout can be in 0-degree and 90-degree directions as in conventional semiconductor manufacturing processes, allowing lithography and etching to be performed. Thus, it is possible to use conventional semiconductor manufacturing devices such as lithography devices.

In conventional semiconductor manufacturing processes, a silicon substrate having a notch or orientation flat formed in a <110> direction is often used. When this silicon substrate is used, the layout may be along the direction turned through 45 degrees.

In the embodiment, a semiconductor device to which the invention is applied is not limited. The invention is applicable to various circuits such as MOSFET, bipolar circuits, resistance elements, and diodes.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device, the method comprising:
laying out a trench pattern along a <100> direction of a (100) silicon substrate;
forming a trench in the silicon substrate based on the laid-out trench pattern; and
annealing the silicon substrate with the trench in a low-pressure reducing atmosphere.

2. The method of claim 1, further comprising forming a mask of the laid-out trench pattern.

3. The method of claim 2, further comprising forming the mask by lithography.

4. The method of claim 3, further comprising etching the silicon substrate by using the mask to form the trench.

5. The method of claim 1, wherein the low-pressure reducing atmosphere is a hydrogen atmosphere at temperatures from 900 to 1100° C. under a pressure less than or equal to 100 Torr.

6. The method of claim 1, wherein a surface of the silicon substrate except the inside of the trench is coated, and the silicon substrate is annealed with the surface coated.

7. The method of claim 4, wherein the silicon substrate is annealed with the mask remaining on a surface of the silicon substrate in which the trench is formed.

8. The method of claim 1, wherein the silicon substrate is processed for crystal identification of the <100> direction.

9. The method of claim 1, further comprising filling the trench with an insulating film to isolate an active area.

10. The method of claim 9, further comprising forming an electrode on the active area.

11. The method of claim 9, further comprising forming a contact on the active area.
